(19) United States
(12) Patent Application Publication
(10) Pub. No.: US 2019/0288176 A1
(43) Pub. Date: Sep. 19, 2019

(54) SUSPENDED JOSEPHSON JUNCTIONS

(71) Applicant: Intel Corporation, Santa Clara, CA (US)

(72) Inventors: Zachary R. Yoscovits, Beaverton, OR (US); David J. Michalak, Portland, OR (US); Jeanette M. Roberts, North Plains, OR (US); Ravi Pillarisetty, Portland, OR (US); James S. Clarke, Portland, OR (US)

(73) Assignee: Intel Corporation, Santa Clara, CA (US)

(21) Appl. No.: 16/302,049

(22) PCT Filed: Jun. 13, 2016
(86) PCT No.: PCT/US2016/037133

§ 371 Date: Nov. 15, 2018

(51) Int. Cl. H01L 39/22; H01L 39/24; G06N 10/00

(52) U.S. Cl. CPC H01L 39/223; G06N 10/00; H01L 39/2493

(57) ABSTRACT

Described herein are structures that include Josephson Junctions to be used in superconducting qubits of quantum circuits disposed on a substrate. In one aspect of the present disclosure, at least a part of a Josephson Junction of a superconducting qubit is suspended over a substrate, forming a gap between at least the portion of the Josephson Junction and the substrate. Moving at least a portion of the Josephson Junction further away from the substrate by suspending at least a part of the Junction over the substrate allows reducing spurious two-level systems present in the vicinity of the Junction, which, in turn, improves on the qubit decoherence problem. Methods for fabricating such structures are disclosed as well.

### TECHNICAL FIELD

This disclosure relates generally to the field of quantum computing, and more specifically, to Josephson Junctions for use in superconducting quantum circuits and to methods of fabricating thereof.

### BACKGROUND

Quantum computing refers to the field of research related to computation systems that use quantum mechanical phenomena to manipulate data. These quantum mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1A provides a schematic illustration of a superconducting quantum circuit, according to some embodiments of the present disclosure.

FIG. 1B provides a schematic illustration of an exemplary physical layout of a superconducting quantum circuit, according to some embodiments of the present disclosure.

FIG. 1C provides a schematic illustration of an exemplary transmon, according to some embodiments of the present disclosure.

FIG. 2 provides a schematic illustration of a quantum computing device, according to some embodiments of the present disclosure.

FIGS. 3A-3C provide a schematic illustration of photoresist masks provided over a substrate for fabricating Josephson Junctions using a double-angle shadow deposition approach, according to some embodiments of the present disclosure.

FIGS. 4A-4C provide a schematic illustration of fabricating Josephson Junctions using a conventional double-angle shadow deposition approach.

FIGS. 5A-5D provide a schematic illustration of fabricating suspended Josephson Junctions, according to some embodiments of the present disclosure.

FIG. 6 provides a flow chart of a method for fabricating suspended Josephson Junctions, according to some embodiments of the present disclosure.

FIG. 7 provides a schematic illustration of a suspended Josephson Junction, according to some embodiments of the present disclosure.

### DETAILED DESCRIPTION

As previously described herein, quantum computing, or quantum information processing, refers to the field of research related to computation systems that use quantum-mechanical phenomena to manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles being generated or interacting in such a way that the state of one particle becomes intertwined with that of the others. Furthermore, the quantum state of each particle cannot be described independently. Instead, the quantum state is given for the group of entangled particles as a whole. Yet another example of quantum-mechanical phenomena is sometimes described as a “collapse” because it asserts that when we observe (measure) particles, we unavoidably change their properties in that, once observed, the particles cease to be in a state of superposition or entanglement (i.e. by trying to ascertain anything about the particles, we collapse their state).

Put simply, superposition postulates that a given particle can be simultaneously in two states, entanglement postulates that two particles can be related in that they are able to instantly coordinate their states irrespective of the distance between them in space and time, and collapse postulates that when one observes a particle, one unavoidably changes the state of the particle and its' entanglement with other particles. These unique phenomena make manipulation of data in quantum computers significantly different from that of classical computers (i.e. computers that use phenomena of classical physics). Classical computers encode data into binary values, commonly referred to as bits. At any given time, a bit is always in only one of two states—it is either 0 or 1. Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being about 10. One of the main challenges resides in protecting qubits from decoherence so that they can stay in their information-holding states long enough to perform the necessary calculations and read out the results. For this reason, materials, structures, and fabrication methods used for building qubits should continuously focus on reducing spurious (i.e. unintentional and undesirable) two-level systems (TLS's), thought to be the dominant source of qubit decoherence. In general, as used in quantum mechanics, a two-level (also referred to as “two-state”) system is a system that can exist in any quantum superposition of two independent and physically distinguishable quantum states. Also for the reason of protection from decoherence, qubits are often operated at cryogenic temperatures, typically just a few degrees or even just a few millidegrees above absolute zero because cryogenic temperatures minimize the detrimental effects of spurious TLS's. None of these challenges ever had to be addressed for classical computers.

As the foregoing illustrates, ability to manipulate and read out quantum states, making quantum-mechanical phenomena visible and traceable, and ability to deal with and improve on the fragility of quantum states of a qubit present unique challenges not found in classical computers. These challenges explain why so many current efforts of the industry and the academics continue to focus on a search for new and improved physical systems whose functionality could approach that expected of theoretically designed qubits. Physical systems for implementing qubits that have been explored until now include e.g. superconducting qubits, single trapped ion qubits, Silicon (Si) quantum dot qubits, photon polarization qubits, etc.

Out of the various physical implementations of qubits listed above, superconducting qubits are promising candidates for building a quantum computer.

Three classes are typically differentiated within a family of superconducting qubits: charge qubits, flux qubits (also known as “persistent current qubits”) and phase qubits, depending on whether a variable that defines the quantum states is, respectively, charge, flux, or phase. In addition to these three classes, there also exist hybrid qubits that are mixtures of two or more of these classes.

Superconducting qubits operate based on the Josephson effect, which refers to a macroscopic quantum phenomenon of supercurrent, i.e. a current that, due to zero electrical resistance, flows indefinitely long without any voltage applied, across a device known as a Josephson Junction. Josephson Junctions are integral building blocks in superconducting quantum circuits where they form a basis of quantum circuit elements that can approximate functionality of theoretically designed qubits. In order for such elements to operate as qubits with sufficient stability (i.e. no or minimal decoherence), areas of a quantum circuit that surround Josephson Junctions should be as free of spurious TLS's as possible. Unfortunately, this is difficult to achieve in practice and, therefore, improvements with respect to this issue would be desirable.

As the foregoing description illustrates, building a quantum computer presents unique challenges not encountered in classical computing. The challenges are unique due to, both, the physics of data manipulation being different from that of classical computers (e.g. superposition, entanglement, and collapse), and the physical systems suitable to build quantum circuits of a quantum computer being different (as will be explained below, the systems should be able to provide substantially lossless connectivity and be able to operate at cryogenic temperatures). Described herein are structures that include Josephson Junctions to be used in quantum circuit components, and methods for fabricating such structures.

Described herein are structures that include Josephson Junctions to be used in qubits of quantum circuits disposed on a substrate. While some descriptions are provided with reference to superconducting qubits, teachings of the present disclosure are applicable to qubits other than superconducting qubits as well as to quantum circuit elements other than qubits, all of which are within the scope of the present disclosure.

In one aspect of the present disclosure, at least a part of a Josephson Junction of a qubit is suspended over a substrate, forming a gap between at least the portion of the Josephson Junction and the substrate. Moving at least a portion of the Josephson Junction away from the substrate by suspending at least a part of the Junction over the substrate allows reducing spurious two-level systems present in the vicinity of the Junction, which, in turn, improves on the qubit decoherence problem. Methods for fabricating such structures are disclosed as well.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Furthermore, in the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations need not be performed in the order of presentation. Operations described may be performed in a different order from the described embodiment(s). Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale.

As used herein, terms indicating what may be considered an idealized behavior, such as e.g. “superconducting” or “lossless”, are intended to cover functionality that may not be exactly ideal but is within acceptable margins for a given application. For example, a certain level of loss, either in terms of non-zero electrical resistance or non-zero amount of spurious TLS's may be acceptable such that the resulting materials and structures may still be referred to by these “idealized” terms. One metric of interest may be the decay rate associated with these losses (e.g. losses either from TLS's or residual resistance), and as long as the decay rate associated with these mechanisms is not worse than needed in order to achieve a fault-tolerant quantum calculation, then the losses are deemed acceptable and the idealized terms (e.g. superconducting or lossless)—appropriate. Specific values associated with an acceptable decay are expected to change over time as fabrication precision will improve and as fault-tolerant schemes may become more tolerant of higher decay rates. An adapted version of this metric, as well as other metrics suitable for a particular application in determining whether certain behavior may be referred to using idealized terms, are within the scope of the present disclosure.

As previously briefly explained above, quantum computing refers to the use of quantum mechanical properties to perform calculations. Some of these properties include superposition and entanglement. Just as classical computers are composed of bits that can either be in a 1 or a 0 state, a quantum computer is composed of quantum bits (i.e., qubits) which have states of |0 [symbol] and |1 [symbol] . Quantum mechanics allows for superpositions of the |0 [symbol] and |1 [symbol] states with a general form of a|0 [symbol] +b|1 [symbol] where a and b are complex numbers. When a qubit state is measured, it collapses to either state 10) with a probability of that happening being |a|², or to state |1 [symbol] with a probability of the latter being |b|². Taking into account the fact that |a|²+|b|²=1 (since the total probability must sum to unity) and ignoring an overall phase factor which does not have any observable effects, the general state can be re-written as

$$cos \frac{θ}{2} \vert 0 〉 + {e}^{i ϕ} sin \frac{θ}{2} \vert 1 〉 ,$$

where φ is the phase difference between the two states.

Entanglement occurs when the interaction between two particles (e.g. two qubits) is such that the states of the two cannot be specified independently, but rather can only be specified for the whole system. This causes the states of the two qubits to be linked together such that measurement of one of the qubits, causes the state of the other qubit to collapse.

In order to realize a quantum computer, a physical system that can act as a qubit is needed. Such a system needs to have at least two states to act as 0 and 1 states. Note that it is not necessary to have a system with exactly only two states if the spacing between each energy level is different, such that each level can be addressed individually. As previously described herein, one type of physical system that could be used to implement qubits is based on use of superconducting materials (superconducting qubits).

In some implementations, namely when superconducting qubits are implemented as transmon qubits, two basic elements of superconducting quantum circuits are inductors and capacitors. However, circuits made using only these two elements cannot make a system with two energy levels because, due to the even spacing between the system's energy levels, such circuits will produce harmonic oscillators with a ladder of equivalent states. A nonlinear element is needed to have an effective two-level quantum state system, or qubit. Josephson Junction is an example of such non-linear, non-dissipative circuit element.

Josephson Junctions may form the central circuit elements of a superconducting quantum computer. A Josephson Junction may include a thin layer of insulator, typically referred to as a barrier or a tunnel barrier, sandwiched between two layers of superconductor. The Josephson Junction acts as a superconducting tunnel junction. Cooper pairs tunnel across the barrier from one superconducting layer to the other. The electrical characteristics of this tunneling are governed by so-called Josephson relations which provide the basic equations governing the dynamics of the Josephson effect:

$$\begin{matrix}I = {I}_{c} sin ϕ & ( 1 ) \\ V = \frac{ℏ}{2 e} \dot{ϕ} & ( 2 )\end{matrix}$$

In these equations, φ is the phase difference in the superconducting wave function across the junction, I_{c} (the critical current) is the maximum current that can tunnel through the junction, which depends on the barrier thickness and the area of the junction, V is the voltage across the Josephson Junction, I is the current flowing through the Josephson Junction, ℏ is the reduced Planck's constant, and e is electron's charge. Equations (1) and (2) can be combined to give an equation (3):

$$V = \frac{ℏ}{2 {eI}_{c} cos ϕ} \dot{I} \qquad ( 3 )$$

Equation (3) looks like the equation for an inductor with inductance L:

$$L = \frac{ℏ}{2 {eI}_{C} cos ϕ} \qquad ( 4 )$$

Since inductance is a function of φ, which itself is a function of I, the inductance of a Josephson Junction is non-linear, which makes an LC circuit formed using a Josephson Junction as the inductor have uneven spacing between its energy states.

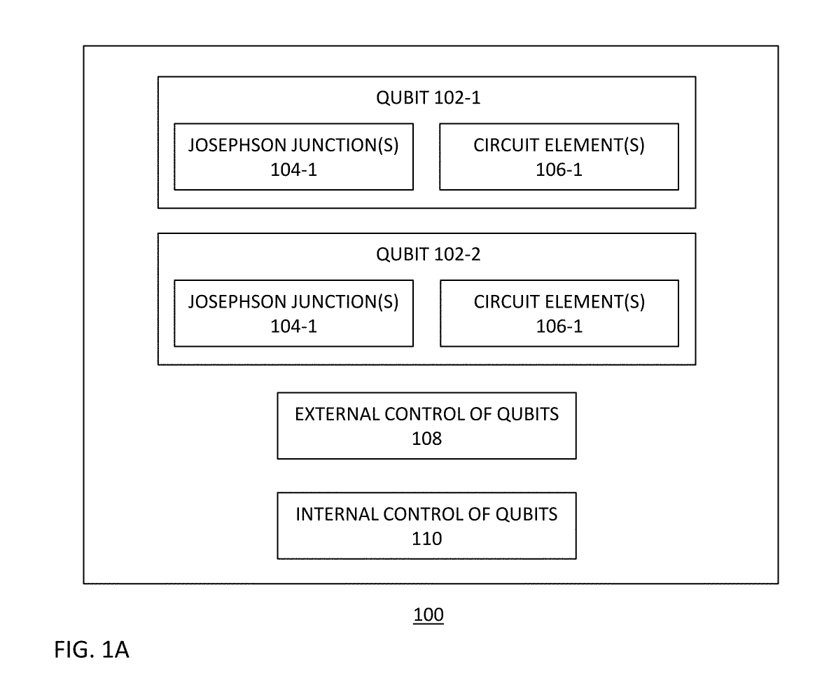

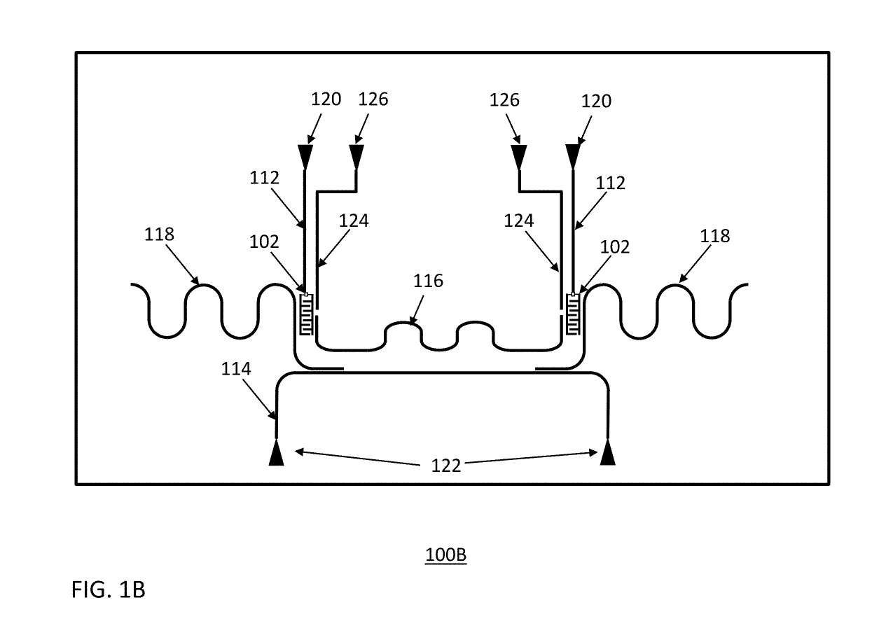

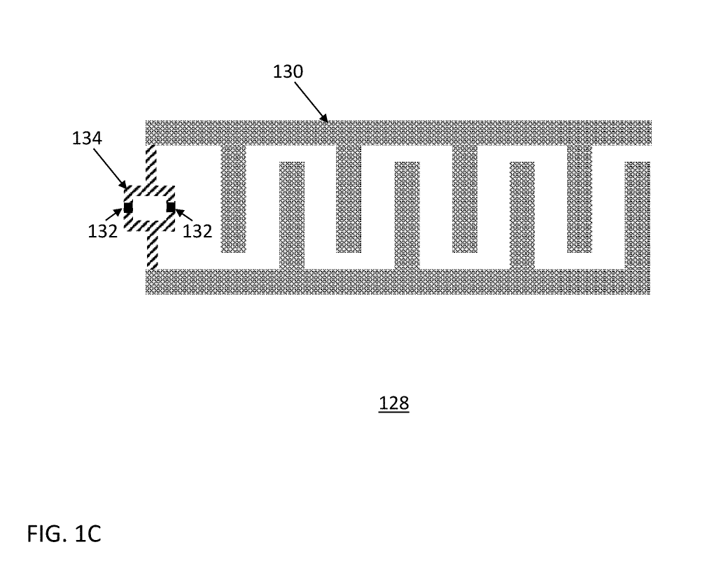

The foregoing provides an illustration of using a Josephson Junction in a transmon, which is one type of superconducting qubit. In other classes of superconducting qubits, Josephson Junctions combined with other circuit elements have similar functionality of providing the non-linearity necessary for forming an effective two-level quantum state, or qubit. In other words, when implemented in combination with other circuit elements (e.g. capacitors in transmons or superconducting loops in flux qubits), one or more Josephson Junctions allow realizing a quantum circuit element which has uneven spacing between its energy levels resulting in a unique ground and excited state system for the qubit. This is illustrated in FIG. 1A, providing a schematic illustration of a superconducting quantum circuit 100, according to some embodiments of the present disclosure. As shown in FIG. 1A, an exemplary superconducting quantum circuit 100 includes two or more qubits 102 (reference numerals following after a dash, such as e.g. qubit 102-1 and 102-2 indicate different instances of the same or analogous element). Each of the superconducting qubits 102 may include one or more Josephson Junctions 104 connected to one or more other circuit elements 106, which, in combination with the Josephson Junction(s) 104, form a non-linear circuit providing a unique two-level quantum state for the qubit. The circuit elements 106 could be e.g. capacitors in transmons or superconducting loops in flux qubits.

As also shown in FIG. 1A, an exemplary superconducting quantum circuit 100 typically includes means 108 for providing external control of qubits 102 and means 110 for providing internal control of qubits 102. In this context, “external control” refers to controlling the qubits 102 from outside of, e.g, an integrated circuit (IC) chip comprising the qubits, including control by a user of a quantum computer, while “internal control” refers to controlling the qubits 102 within the IC chip. For example, if qubits 102 are transmon qubits, external control may be implemented by means of flux bias lines (also known as “flux lines” and “flux coil lines”) and by means of readout and drive lines (also known as “microwave lines” since qubits are typically designed to operate with microwave signals), described in greater detail below. On the other hand, internal control lines for such qubits may be implemented by means of resonators, e.g., coupling and readout resonators, also described in greater detail below.

Any one of the qubits 102, the external control means 108, and the external control means 110 of the quantum circuit 100 may be provided on, over, or at least partially embedded in a substrate (not shown in FIG. 1A). A substrate may include any substrate suitable for realizing quantum circuit components, as described above. In one implementation, the substrate may be a crystalline substrate such as, but not limited to a silicon or a sapphire substrate, and may be provided as a wafer or a portion thereof. In other implementations, the substrate may be non-crystalline. In general, any material that provides sufficient advantages (e.g. sufficiently good electrical isolation and/or ability to apply known fabrication and processing techniques) to outweigh the possible disadvantages (e.g. negative effects of spurious TLS's), and that may serve as a foundation upon which a quantum circuit may be built, falls within the spirit and scope of the present disclosure. Additional examples of substrates include silicon-on-insulator (SOI) substrates, III-V substrates, and quartz substrates.

As previously described herein, within superconducting qubit implementations, three classes are typically distinguished: charge qubits, flux qubits, and phase qubits. Transmons, a type of charge qubits with the name being an abbreviation of “transmission line shunted plasma oscillation qubits”, are particularly encouraging because they exhibit reduced sensitivity to charge noise. FIG. 1B provides a schematic illustration of an exemplary physical layout of a superconducting quantum circuit 100B where qubits are implemented as transmons, according to some embodiments of the present disclosure.

Similar to FIG. 1A, FIG. 1B illustrates two qubits 102. In addition, FIG. 1B illustrates flux bias lines 112, microwave lines 114, a coupling resonator 116, a readout resonator 118, and wirebonding pads 120 and 122. The flux bias lines 112 and the microwave lines may be viewed as examples of the external control means 108 shown in FIG. 1A. The coupling resonator 116 and the readout resonator 118 may be viewed as examples of the internal control means 110 shown in FIG. 1A.

Running a current through the flux bias lines 112, provided from the wirebonding pads 120, allows tuning (i.e. changing) the frequency of the corresponding qubits 102 to which each line 112 is connected. In general, it operates in the following manner. As a result of running the current in a particular flux bias line 112, magnetic field is created around the line. If such a magnetic field is in sufficient proximity to the qubit 102, e.g. by a portion of the flux bias line 112 being provided next to the qubit 102, the magnetic field couples to the qubit, thereby changing the spacing between the energy levels of the qubit. This, in turn, changes the frequency of the qubit since the frequency is directly related to the spacing between the energy levels via Planck's equation. The Planck's equation is E=hv, where E is the energy (in this case the energy difference between energy levels of a qubit), h is the Planck's constant and v is the frequency (in this case the frequency of the qubit). As this equation illustrates, if E changes, then v changes. Provided there is sufficient multiplexing, different currents can be sent down each of the flux lines allowing for independent tuning of the various qubits.

The state(s) of each qubit 102 may be read by way of its corresponding readout resonator 118. As explained below, the qubit 102 induces a resonant frequency in the readout resonator 118. This resonant frequency is then passed to the microwave lines 114 and communicated to the pads 122.

To that end, a readout resonator 118 may be provided for each qubit. The readout resonator 118 may be a transmission line that includes a capacitive connection to ground on one side and is either shorted to the ground on the other side (for a quarter wavelength resonator) or has a capacitive connection to ground (for a half wavelength resonator), which results in oscillations within the transmission line (resonance), with the resonant frequency of the oscillations being close to the frequency of the qubit. The readout resonator 118 is coupled to the qubit by being in sufficient proximity to the qubit 102, more specifically in sufficient proximity to the capacitor of the qubit 102, when the qubit is implemented as a transmon, either through capacitive or inductive coupling. Due to a coupling between the readout resonator 118 and the qubit 102, changes in the state of the qubit 102 result in changes of the resonant frequency of the readout resonator 118. In turn, because the readout resonator 118 is in sufficient proximity to the microwave line 114, changes in the resonant frequency of the readout resonator 118 induce changes in the current in the microwave line 114, and that current can be read externally via the wirebonding pads 122.

The coupling resonator 116 allows coupling different qubits together in order to realize quantum logic gates. The coupling resonator 116 is similar to the readout resonator 118 in that it is a transmission line that includes capacitive connections to ground on both sides (i.e. a half wavelength resonator), which also results in oscillations within the coupling resonator 116. Each side of the coupling resonator 116 is coupled (again, either capacitively or inductively) to a respective qubit by being in sufficient proximity to the qubit, namely in sufficient proximity to the capacitor of the qubit, when the qubit is implemented as a transmon. Because each side of the coupling resonator 116 has coupling with a respective different qubit, the two qubits are coupled together through the coupling resonator 116. In this manner, state of one qubit depends on the state of the other qubit, and the other way around. Thus, coupling resonators may be employed in order to use a state of one qubit to control a state of another qubit.

In some implementations, the microwave line 114 may be used to not only readout the state of the qubits as described above, but also to control the state of the qubits. When a single microwave line is used for this purpose, the line operates in a half-duplex mode where, at some times, it is configured to readout the state of the qubits, and, at other times, it is configured to control the state of the qubits. In other implementations, microwave lines such as the line 114 shown in FIG. 1B may be used to only readout the state of the qubits as described above, while separate drive lines such as e.g. drive lines 124 shown in FIG. 1B, may be used to control the state of the qubits. In such implementations, the microwave lines used for readout may be referred to as readout lines (e.g. readout line 114), while microwave lines used for controlling the state of the qubits may be referred to as drive lines (e.g. drive lines 124). The drive lines 124 may control the state of their respective qubits 102 by providing, using e.g. wirebonding pads 126 as shown in FIG. 1B, a microwave pulse at the qubit frequency, which in turn stimulates (i.e. triggers) a transition between the 0 and 1 state of the qubit. By varying the length of this pulse, a partial transition can be stimulated, giving a superposition of the 0 and 1 states of the qubit.

Flux bias lines, microwave lines, coupling resonators, drive lines, and readout resonators, such as e.g. those described above, together form interconnects for supporting propagation of microwave signals. Further, any other connections for providing direct electrical interconnection between different quantum circuit elements and components, such as e.g. connections from electrodes of Josephson Junctions to plates of the capacitors or to superconducting loops of superconducting quantum interference devices (SQUIDS) or connections between two ground lines of a particular transmission line for equalizing electrostatic potential on the two ground lines, are also referred to herein as interconnects. Still further, the term “interconnect” may also be used to refer to elements providing electrical interconnections between quantum circuit elements and components and non-quantum circuit elements, which may also be provided in a quantum circuit, as well as to electrical interconnections between various non-quantum circuit elements provided in a quantum circuit. Examples of non-quantum circuit elements which may be provided in a quantum circuit may include various analog and/or digital systems, e.g. analog to digital converters, mixers, multiplexers, amplifiers, etc.

In various embodiments, the interconnects as shown in FIG. 1B could have different shapes and layouts. For example, some interconnects may comprise more curves and turns while other interconnects may comprise less curves and turns, and some interconnects may comprise substantially straight lines. In some embodiments, various interconnects may intersect one another, in such a manner that they don't make an electrical connection, which can be done by using e.g. a bridge, bridging one interconnect over the other. As long as these interconnects operate in accordance with use of these interconnects as known in the art for which some exemplary principles were described above, quantum circuits with different shapes and layouts of the interconnects than those illustrated in FIG. 1B are all within the scope of the present disclosure.

Coupling resonators and readout resonators may be configured for capacitive coupling to other circuit elements at one or both ends in order to have resonant oscillations, whereas flux bias lines and microwave lines may be similar to conventional microwave transmission lines because there is no resonance in these lines. Each one of these interconnects may be implemented as a coplanar waveguide, which is one type of transmission line. A stripline is another type of transmission line. Typical materials to make the interconnects include aluminum (Al), niobium (Nb), niobium nitride (NbN), titanium nitride (TiN), and niobium titanium nitride (NbTiN), all of which are particular types of superconductors. However, in various embodiments, other suitable superconductors may be used as well.

As previously described herein, FIG. 1B illustrates an embodiment specific to transmons. Subject matter is not limited in this regard and may include other embodiments of quantum circuits implementing other types of superconducting qubits that would also utilize Josephson Junctions as described herein, all of which are within the scope of the present disclosure.

FIG. 1C illustrates an exemplary transmon 128 which could be used as any one of the qubits 102, according to some embodiments of the present disclosure. Presence of a capacitor 130 of such a size that capacitive energy is significantly larger than the Josephson energy in a qubit of FIG. 1C indicates that the qubit is a transmon. The capacitor 130 is configured to store energy in an electrical field as charges between the plates of the capacitor.

The capacitor 130 is depicted as an interdigitated capacitor, a particular shape of capacitor that provides a large capacitance with a small area, however, in various embodiments, other shapes and types of capacitors may be used as well. For example, such a capacitor could be implemented simply as two parallel plates with vacuum in between. Furthermore, in various embodiments, the capacitor 130 may be arranged in any direction with respect to the SQUID or a single Josephson Junction, not necessarily as shown in FIG. 1C.

In addition, the transmon illustrated in FIG. 1C includes two Josephson Junctions 132 incorporated into a superconducting loop 134. The two Josephson Junctions 132 and the superconducting loop 134 together form a superconducting quantum interference device (SQUID). Magnetic fields generated by the flux bias line 112 connected to the qubit extend to the SQUID (i.e. current in the flux bias line 112 create magnetic fields around the SQUID), which in turn tunes the frequency of the qubit.

In other embodiments, a SQUID could include only one Josephson Junction, or a transmon could be implemented with a single Josephson Junction without the superconducting loop. A single Josephson Junction without the SQUID is insensitive to magnetic fields, and thus, in such an implementation, flux bias lines 112 may not be used to control the frequency of the transmon.

While FIGS. 1A and 1B illustrate examples of quantum circuits comprising only two qubits 102, embodiments with any larger number of qubits are possible and are within the scope of the present disclosure. At least one of the one or more qubits 102 shown in FIGS. 1A-1C may comprise suspended Josephson Junction structures as described herein.

Furthermore, while the present disclosure includes references to microwave signals, this is done only because current qubits are designed to work with such signals because the energy in the microwave range is higher than thermal excitations at the temperature that qubits are operated at. In addition, techniques for the control and measurement of microwaves are well known. For these reasons, typical frequencies of superconducting qubits are in 5-10 gigahertz (GHz) range, in order to be higher than thermal excitations, but low enough for ease of microwave engineering. However, advantageously, because excitation energy of superconducting qubits is controlled by the circuit elements, these qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

In various embodiments, quantum circuits such as the one shown in FIGS. 1A-1B may be used to implement components associated with a quantum integrated circuit (IC). Such components may include those that are mounted on or embedded in a quantum IC, or those connected to a quantum IC. The quantum IC may be either analog or digital and may be used in a number of applications within or associated with quantum systems, such as e.g. quantum processors, quantum amplifiers, quantum sensors, etc., depending on the components associated with the integrated circuit. The integrated circuit may be employed as part of a chipset for executing one or more related functions in a quantum system.

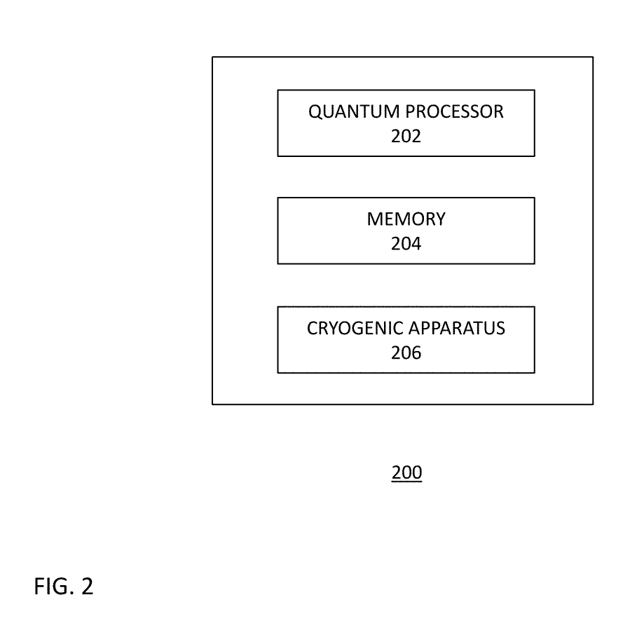

FIG. 2 provides an illustration of quantum computing device, e.g. a quantum computer, 200, according to some embodiments of the present disclosure. The computing device 200 may be any electronic device that processes quantum information. In some embodiments, the computing device 200 may include a number of components, including, but not limited to, a quantum processor 202, a memory 204, and a cryogenic apparatus 206, as shown in FIG. 2. Each of the quantum processor 202 and the memory 204 may include one or more quantum circuits comprising suspended Josephson Junction structures as described herein, e.g. quantum circuits and Josephson Junctions as illustrated in FIGS. 1A-1C.

The processor 202 may be a universal quantum processor or a specialized quantum processor configured to run quantum simulations, or one or more of particular quantum algorithms. The term “processor” may refer to any device or portion of a device that processes electronic data from registers and/or memory to transform that electronic data into other electronic data that may be stored in registers and/or memory. In some embodiments, the processor 202 may be configured to execute algorithms that may be particularly suitable for quantum computers, such as e.g. cryptographic algorithms that utilize prime factorization, algorithms to optimize chemical reactions, or protein folding algorithms. The term “processor” may refer to any device or portion of a device that processes quantum information.

In various embodiments, the computing device 200 may include other components not shown in FIG. 2, such as e.g. one or more of a controller, I/O channels/devices, supplementary microwave control electronics, multiplexer, signal mixers, a user interface, as well as other quantum devices such as e.g. quantum amplifiers, quantum sensors, which quantum devices may also implement certain embodiments of the present disclosure.

In various embodiments, the computing device 200 may be included within a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 200 may be any other quantum electronic device that processes data by utilizing quantum mechanical phenomena.

In order to highlight the advantages offered by novel Josephson Junction structures proposed herein, it would be helpful to first explain how Josephson Junctions may be fabricated using a so-called double-angle shadow deposition approach (also sometimes referred to as “double-angle shadow evaporation” or “hanging resist” approach). The name “double-angle shadow deposition/evaporation” reflects the fact that the method involves metal deposition, typically carried out by metal evaporation, at two different angles of incidence with respect to the substrate (hence, double-angle). The name further reflects the fact that metal deposition is performed through a hanging photoresist mask which casts a shadow on at least a part of the substrate, obscuring metal deposition on that part (hence, shadow deposition/evaporation).

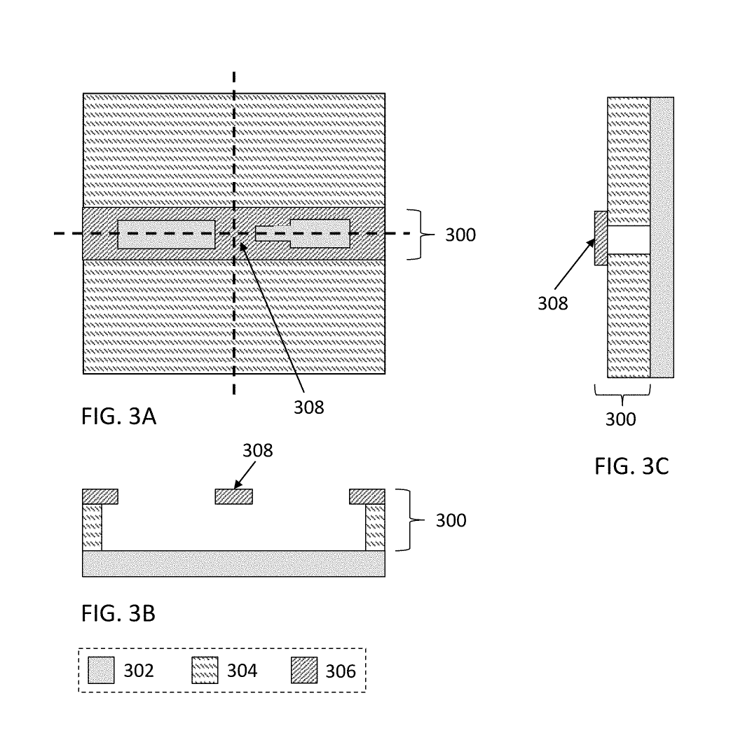

FIGS. 3A-3C provide a schematic illustration of one example of a photoresist mask 300 provided over a substrate 302 for fabricating Josephson Junctions using a double-angle shadow deposition approach, according to some embodiments of the present disclosure. Each of FIGS. 3A-3C provides a view of the same photoresist mask 300 over the substrate 302, but perspectives of these views are different. FIG. 3A provides a top-down view (i.e. a view from a point above the substrate 302). FIG. 3B provides a cross-sectional view with a cross-section of the structure of FIG. 3A taken along a horizontal dashed line shown in FIG. 3A. Finally, FIG. 3C provides a cross-sectional view with a cross-section of the structure of FIG. 3A taken along a vertical dashed line shown in FIG. 3A. A legend provided within a dashed box at the bottom of FIGS. 3A-3C illustrates patterns used to indicate different elements shown in FIGS. 3A-3C, so that the FIGs are not cluttered by many reference numerals.

Josephson Junctions may be created by a double-angle shadow deposition approach using a two-layer photoresist mask 300 that includes a bottom photoresist layer 304 and a top photoresist layer 306 as shown in FIGS. 3A-3C. The bottom layer 306 is undercut from the top layer 304 in that some portions of the top layer 304 hang, or are suspended, over the bottom layer 306. The bottom layer 306 is undercut in such a manner that the top layer 304 of photoresist forms a suspended bridge 308, known as a Dolan bridge, over a section of the substrate 302. Fabricating such undercuts in photoresist may include additional or other well-known techniques according to some embodiments.

In various embodiments, any kind of photoresist patterning techniques as known in the art may be used for creating photoresist layers 304 and 306 as shown in FIGS. 3A-3C. For example, in an embodiment, patterning includes depositing a first layer of photoresist for forming the bottom layer 304 over the substrate 302. The photoresist may be a positive or negative resist and may include for example, poly(methyl methacrylate), poly(methyl glutarimide), DNQ/novolac, or SU-8 (an expoxy based negative resist). The photoresist may be deposited by a casting process such as, for example, spin-coating. Spin coating may be performed at 1 to 10,000 rpm, including all values and ranges therein, for a time period in the range of 1 second to 10 seconds, including all values and ranges therein.

The second layer of photoresist 306, comprising similar material to those mentioned above is deposited using similar methods to those discussed above.

The photoresist may then be patterned by optically projecting an image of a desired pattern onto the photoresist using photolithography, such as optical photolithography, immersion photolithography, deep UV lithography, extreme UV lithography, electron-beam direct-write lithography, or other techniques, wherein the wavelength of projected light may be up to 436 nm, including all values and ranges from 157 nm to 436 nm, such as 157 nm, 193 nm, 248 nm, etc. A developer, such as tetramethylammonium hydroxide TMAH (with or without surfactant) at a concentration of in the range of 0.1 N to 0.3 N, may be applied to the photoresist, such as by spin-coating, and portions of the photoresist are removed to expose regions of the underlying substrate 302 correlating to the desired pattern. The photoresist materials can be chosen such that the single exposure causes larger features to be patterned in the bottom photoresist 304 than those patterned in the top photoresist 306.

In some embodiments, baking of the substrate 302 may occur before or after any of the above actions. For example, the substrate 302 may be prebaked to remove surface water. In some embodiments, prebaking may be performed at a temperature in the range of 200° C. to 400° C., including all values and ranges therein, for a time of 30 to 60 minutes, including all values and ranges therein. After application of the photoresist, a post application bake may occur, wherein at least a portion of the solvents in the photoresist are driven off. A post application bake is, for example, performed at temperatures in the range of 70° C. to 140° C., including all values and ranges therein, for a time period in the range of 60 seconds to 240 seconds, including all values and ranges therein. After patterning, the resist may be hard baked at a temperature in the range of 100° C. to 300° C., including all values and ranges therein, for a time period of 1 minute to 10 minutes, including all values and ranges therein.

While FIGS. 3A-3C and other descriptions provided herein refer to a mask formed with two layers of photoresist, in other embodiments, any other mask having a suspended bridge as described above may be used and are within the scope of the present disclosure. For example, one mask alternative to the two-layer photoresist mask described above could include a germanium resist layer as the top layer 306 having at least some parts that are suspended over a polymeric resist patterned to form the bottom layer 304.

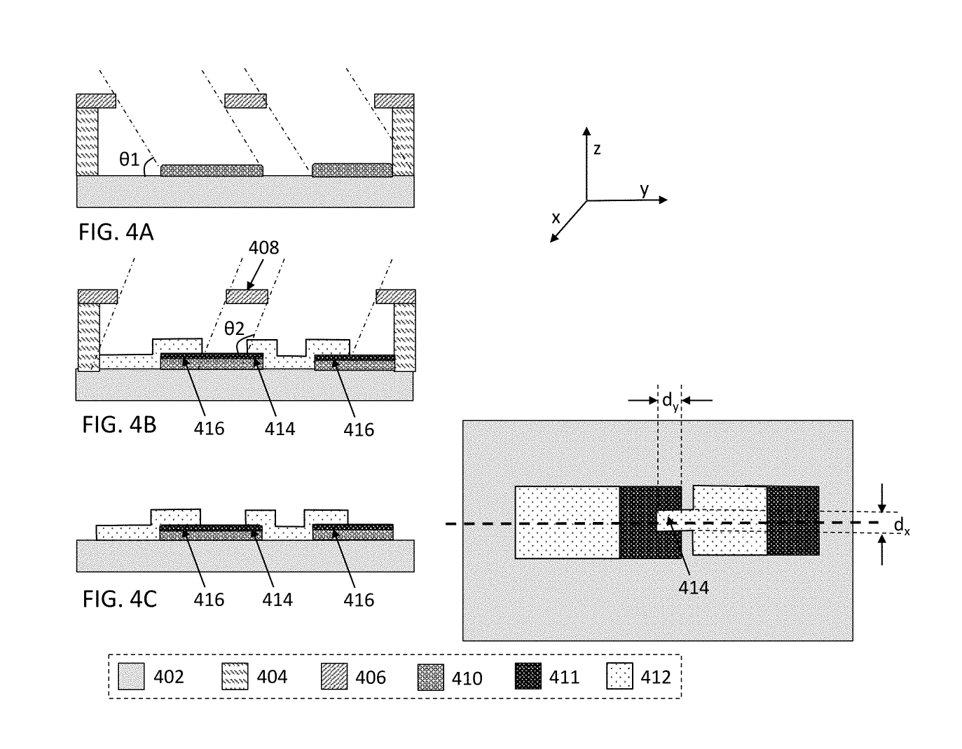

In order to form a Josephson Junction, metals may be deposited through a mask with a suspended bridge such as e.g. the ones described above. FIGS. 4A-4C provide a schematic illustration of fabricating Josephson Junctions using a conventional double-angle shadow deposition approach.

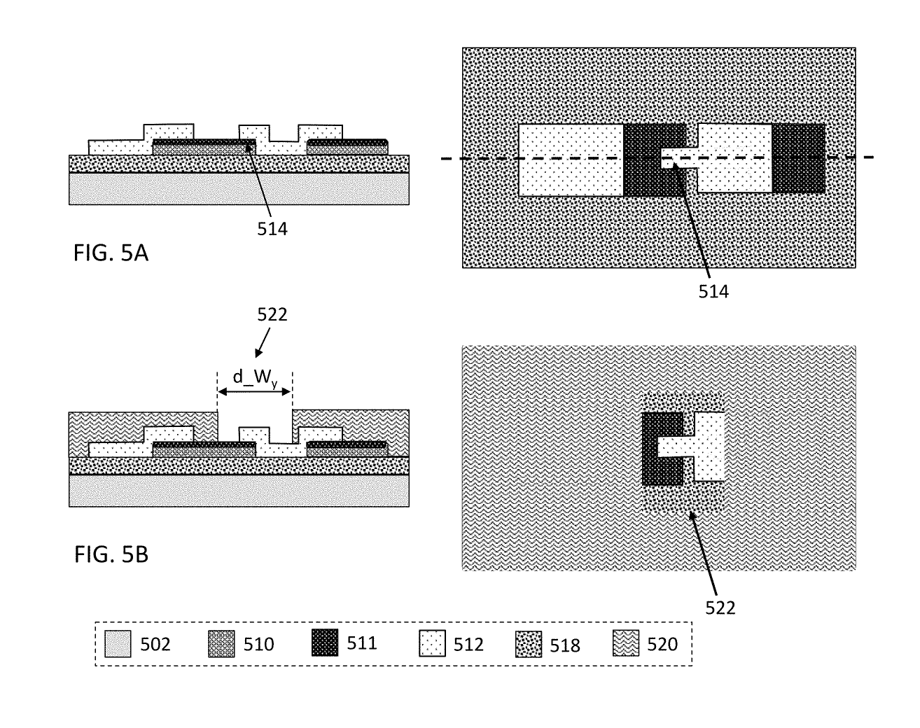

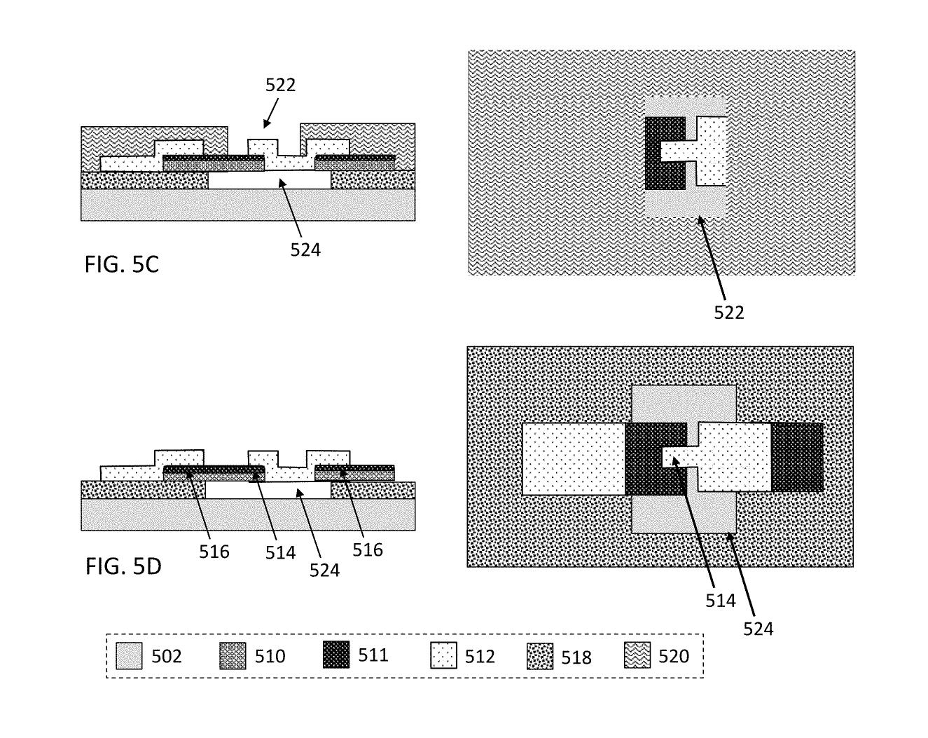

Each of FIGS. 4A-4C illustrates a result of different subsequent fabrication steps. FIG. 4C provides two views of the same structure. The view on the right side of FIG. 4C is a top-down view (i.e. a view similar to that shown in FIG. 3A). The view on the left side of FIG. 4C is a cross-sectional view with a cross-section of the structure of FIG. 4C taken along a horizontal dashed line shown in FIG. 4C (i.e. a view similar to that shown in FIG. 3B). Each of FIGS. 4A and 4B only provide a cross-sectional view similar to that of the left side of FIG. 4C but at an earlier fabrication step. Similar to FIGS. 3A-3C, and also applicable to FIGS. 5A-5D described below, a legend provided within a dashed box at the bottom of FIGS. 4A-4C and at the bottom of FIGS. 5A-5D illustrates patterns used in the respective figures to indicate different elements. Moreover, similar reference numerals in FIGS. 3A-3C, FIGS. 4A-4C, and FIGS. 5A-5D are used to illustrate analogous elements in the figures. For example, reference numerals 302, 402, and 502 shown, respectively, in FIGS. 3, 4, and 5 refer to a substrate, reference numerals 304 and 404—to a bottom mask layer, reference numerals 414 and 514—to a central Josephson Junction, and so on. When provided with reference to one of the figures, discussions of these elements are applicable to other figures, unless stated otherwise. Thus, in the interests of brevity, discussions of similar elements are not repeated for each of the figures but, rather, the differences between the figures are described.

As previously described herein, a Josephson Junction comprises a thin layer of insulator sandwiched between two layers of superconductors, the insulating layer acting as the barrier in a superconducting tunnel junction. Such a device may be fabricated by, first, depositing a layer of a first superconductor 410 on the substrate 402, as shown in FIG. 4A, through the two-layer mask such as e.g. the one shown in FIGS. 3A-3C. The first superconductor is deposited at an angle with respect to the substrate 402, as shown in FIG. 4A with an angle θ1. Slanted dotted-dashed lines in FIG. 4A illustrate the direction of deposition of the first superconductor 410. Typically the first superconductor 410 is aluminum (Al) because this is a material that is the easiest to deposit using this method. However, in principle any other superconducting materials may be used such as e.g. niobium (Nb), niobum nitride (NbN), niobium titanium nitride (NbTiN), titanium nitride (TiN), molybdenum rhenium (MoRe), etc., or any alloy of two or more superconducting materials. A layer of the first superconductor 410 may have a thickness between e.g. 10 and 300 nm, preferably between 40 and 100 nm.

The first superconductor 410 forms a base electrode of the Josephson Junction. A layer of insulator 411 may then be provided over the first superconductor 410 to form a tunnel barrier of the Josephson Junction. Typically, this is done by oxidizing the first superconductor 410 to form a layer of oxide on its surface. Such an oxide may have a thickness between e.g. 1 and 5 nm, typically for qubit applications between 2 and 3 nm.

After the layer of insulator forming the tunnel barrier is provided on the first superconductor 410, a second superconductor 412 is deposited through the mask but at a different angle with respect to the substrate 402 than 01. FIG. 4B illustrates the second angle as an angle θ2 and slanted dotted-dashed lines in FIG. 4B illustrate the direction of deposition of the second superconductor 412. In some embodiments, the first and the second superconductors 410, 412 are deposited at the opposite angles, if measured with respect to a normal to the substrate 402. Similar to the first superconductor 410, typically the second superconductor 420 is aluminum (Al), but in principle any other superconducting materials may be used such as e.g. Nb, NbN, NbTiN, TiN, MoRe, etc, or any alloy of two or more superconducting materials. In various embodiments, the first and second superconductors 410 and 412 may be made from the same or different superconducting materials. A layer of the second superconductor 412 may have a thickness between e.g. 10 and 300 nm, typically between 40 and 100 nm. The layer of the second superconductor 412 may have other suitable thicknesses in other embodiments.

The second superconductor 412 forms a counter electrode (i.e. counter to the base electrode formed by the first superconductor 410) of the Josephson Junction.

In various embodiments, the first and second superconductors 410, 412 may be deposited using any suitable process, including e.g. a non-conformal process. For example a physical vapor deposition process, such as e.g. evaporative deposition, magnetron sputtering, or e-beam deposition, may be used. In other embodiments, conformal deposition processes e.g. followed by selective etching, may be used to form the first and second superconductors.

After deposition of the second superconductor 412, the deposition mask may be removed, removing with it any first and/or second superconductor 410, 412 deposited on top of it. If the deposition mask is a two-layer photoresist mask, the mask may be removed e.g. via a process such as aching, where the photoresist is exposed to oxygen or fluorine, which combines with the photoresist to form ash.

In general, the above-described process of creating patterned structures of one or more target materials (in this case, structures made of the first and second superconductors 410, 412) on the surface of a substrate using a sacrificial material such as photoresist is referred to as a lift-off method. Lift-off is a type of an additive technique, as opposed to subtracting techniques like etching, and may be applied in cases where a direct etching of structural material would have undesirable effects on one or more layers below.

The resulting Josephson Junction 414 remains on the substrate 402 after the deposition mask is removed as shown in FIG. 4C. The Junction 414 is formed by the small region of overlap under the photoresist bridge 408 (i.e. the area under the bridge 408 where the first superconductor 410, covered with a layer of a thin insulating material is overlapped by the second superconductor 412). Dimensions of the Junction 414 along x-axis and y-axis, shown in FIG. 4C as dₓ and d_{y}, respectively, are typically between 50 and 1000 nm for any of dₓ and d_{y}. The Junction 414 may include other suitable dimensions in other embodiments.

It should be noted that as a result of performing the double-angle shadow deposition as described above, junctions of the first and second superconductors may also be formed on each side of the Josephson Junction 414, such junctions shown in FIGS. 4B and 4C as Junctions 416. However, because these junctions are of much larger dimensions than the Josephson Junction 414, e.g. measured several thousands of nm in the x-direction and hundreds of nm or more in the y-direction, they are essentially infinite for the Josephson effect to take place and, therefore, act as superconductors rather than Josephson Junctions.

One major source of loss and thus decoherence in superconducting qubits are spurious TLS's in the areas surrounding Josephson Junctions. In context of superconducting qubits, the dominant source of decoherence is thought to be TLS's in non-crystalline dielectric materials. These TLS's are thought to be either an electron or an ion that can tunnel between two spatial states, which are caused either by defects in the crystal structure of the substrate or through polar impurities such as hydroxyl (OH—) groups.

One mechanism of how spurious TLS's can lead to decoherence in a qubit is based on the idea that, if the TLS's are in a close proximity to the qubit and are in resonance with the qubit (i.e. when the frequency of a spurious TLS is close to the frequency of a qubit), they can couple to it. When this happens, spurious TLS's and the qubit exchange energy in the form of photons emitted by the qubit and absorbed by the spurious TLS's and may be viewed as a spurious TLS-qubit system having a certain combined energy. When combined energy of such a TLS-qubit system decays through phonon emission from the spurious TLS's, the TLS-qubit system relaxes, leading to decoherence of the qubit.

Spurious TLS's that lead to qubit decoherence by this mechanism may be present in the barrier of the tunnel junction 414 (i.e. in the insulator between the first and second superconductor layers of the junction). Such barriers are typically formed by diffusive oxidation of aluminum, which is known to have a measurable density of TLS's.

Another source of spurious TLS's that may lead to qubit decoherence by the mechanism described above is the surface of the second superconductor 412 (i.e. TLS's present at the superconductor-air interface). Yet another source of spurious TLS's may be an interface between the substrate 402 and the first superconductor 410.

Embodiments of the present disclosure are based on an insight that reducing the interface area between a substrate and a bottom superconductor of a Josephson Junction will reduce the total amount of spurious TLS's in close proximity to the qubit and, thus, would improve on the decoherence problems of the qubit. To achieve reduction of the substrate-superconductor interface, at least a part of the Josephson Junction may be suspended (i.e. float in free space) over the substrate. Such a configuration allows moving the interface of the qubit with the substrate farther away from the junction to where there is less electric field, which should reduce coupling to the spurious TLS's and reduce loss in the microwave region. An example of a structure where an entire Josephson Junction is suspended over a substrate is shown in FIG. 5D. However, in other embodiments, suspending even a portion of a Josephson Junction over a substrate would be expected to produce improvements with respect to qubit decoherence, all of which embodiments are within the scope of the present disclosure.

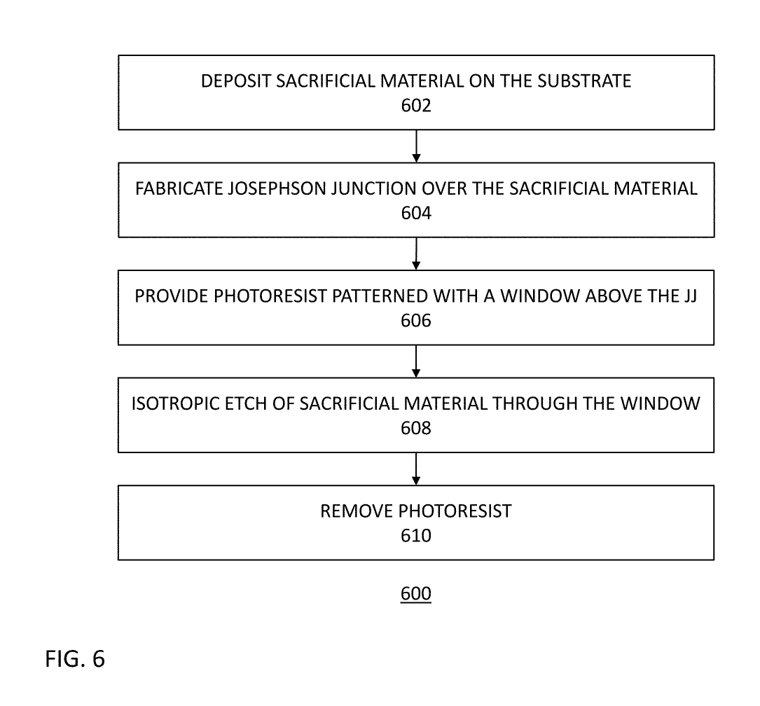

FIGS. 5A-5D provide a schematic illustration of fabricating suspended Josephson Junctions, according to some embodiments of the present disclosure. Similar to FIGS. 4A-4C, each of FIGS. 5A-5D illustrates a result of different subsequent fabrication steps. Furthermore, each of FIGS. 5A-5D provides two views of the same structure, similar to those shown in FIG. 4C. Namely, the view on the right side of each of FIGS. 5A-5D is a top-down view (i.e. a view similar to that shown on the right side of FIG. 4C), while the view on the left side of each of FIGS. 5A-5D is a cross-sectional view with a cross-section of the structure of these figures taken along a horizontal dashed line shown in FIG. 5A (i.e. a view similar to that shown on the left side of FIG. 4C). FIGS. 5A-5D will now be described with reference to FIG. 6 providing a flow chart of a method 600 for fabricating suspended Josephson Junctions, according to some embodiments of the present disclosure, which method could be used for fabricating the structures of FIGS. 5A-5D.

In various embodiments, any suitable techniques may be used to manufacture the suspended Josephson Junctions disclosed herein. FIG. 6 is a flow diagram of one illustrative method 600 of manufacturing such devices, in accordance with various embodiments. Although the operations discussed below with reference to the method 600 are illustrated in a particular order and depicted once each, these operations may be repeated or performed in a different order (e.g., in parallel), as suitable. Additionally, various operations may be omitted, as suitable. Various operations of the method 600 may be illustrated with reference to one or more of the embodiments discussed above, but the method 600 may be used to manufacture any suitable quantum circuit element comprising one or more Josephson Junctions (including any suitable ones of the embodiments disclosed herein).

The method 600 may begin with providing a layer of insulating sacrificial material 518 over a substrate 502 (process 602 of FIG. 6). Since such a material will need to later be etched to achieve undercutting of the sacrificial material 518 under the Josephson Junction 514 to provide a gap between at least a portion of the Josephson Junction and the substrate, e.g. using isotropic etching, etching properties of potential candidate materials are to be considered when selecting a suitable material to be used as the sacrificial layer 518. Besides appropriate etching characteristics, some other considerations in selecting a suitable material may include e.g. possibilities of smooth film formation, low shrinkage and outgassing, and good dielectric properties (such as e.g. low electrical leakage, suitable value of a dielectric constant, and thermal stability). Examples of dielectric materials that may be used as the sacrificial material 518 include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass.

In some embodiments, the sacrificial material 518 may be provided as a layer of oxide by oxidizing the top surface of the substrate 502. In other embodiments, the sacrificial material 518 may include an oxide deposited over the substrate 502 using e.g. In still other embodiments, the sacrificial material 518 may include a dielectric material formed over the substrate 502 using coating techniques involving cross-linking of liquid precursors into solid dielectric materials.

Next, a Josephson Junction is formed over at least a portion, but preferably over all of, the sacrificial material (process 604). FIG. 5A illustrates the substrate 502 covered with the sacrificial material 518 and having a Josephson Junction 514 provided over the sacrificial material 518. To that end, any suitable methods for forming a Josephson Junction may be used. For example, in some embodiments, the Josephson Junction 514 may be formed using the double-angle shadow deposition approach as described above with reference to FIGS. 4A-4C except that the first superconductor 510 is provided over the sacrificial material 518 and not over the substrate. However, in other embodiments, other methods for forming Josephson Junctions may be appropriate as well, all of which embodiments are within the scope of the present disclosure.

While an exemplary layer of insulator 511 that forms the tunnel barrier of the Josephson Junction as shown in FIGS. 5A-5D is shown to cover all of the first superconductor 510, in other embodiments the insulator 511 may be provided only over the part of the first superconductor 510 that will form a Josephson Junction.

Once the Josephson Junction 514 is formed, the entire structure may be covered with a layer of photoresist 520 patterned to form a window over at least a portion, but preferably over the entire, Josephson Junction (JJ) (process 606). In addition, the window should be such as to expose a portion of the underlying sacrificial material 518 so that it can be etched via the window in a subsequent fabrication step. In various embodiments, any kind of photoresist patterning techniques as known in the art may be used, such as e.g. those described above with reference to creating photoresist layers of FIGS. 3A-3C.

FIG. 5B illustrates a layer of photoresist 520 having a window 522 of width d_W_{y} in the y-direction (the same x, y, z notation as shown for FIGS. 4A-4C is used for FIGS. 5A-5D). For example, dimensions of the window 522 in the x- and y-directions could be, respectively, between 200 and 10000 nm for both the x-axis and y-axis.

Next, the sacrificial material 518 is etched through the window 522 (box 608). Preferably, the etching process used is an isotropic etch so that at least a portion of the sacrificial material under the Josephson Junction 514 is also etched, even though it is not exposed via the window 522 (i.e. at least a portion of the sacrificial material under the Josephson Junction 514 is undercut). Isotropic etching etches in multiple directions (both vertically and horizontally), unlike e.g. dry etching which only etches in a single direction, and, therefore, can be used to achieve undercutting of the sacrificial material 518 under the Junction 514, thereby providing a void or a gap between the Junction 514 and the substrate. Any substance suitable for isotropically etching the sacrificial material 518 may be used. In various embodiments, an etchant may be e.g. corrosive liquid, such as e.g. hydrofluoric acid (HF) or a chemically active ionized gas (i.e. plasma). As a result of the isotropic etching, a gap is formed at least under a portion of, but preferably under the entire, Josephson Junction 514 according to one embodiment. FIG. 5C illustrates this with a gap 524 under all of the Josephson Junction 514. Note that the left side drawings of FIG. 5C illustrates the gap 524 explicitly, while the view of the right side drawing of this figure implies having the gap 524 because it shows that the window 522 exposes the substrate 502 (as opposed to e.g. the right side drawing of FIG. 5B showing that the window 522 exposes the sacrificial material 518). In some embodiments, the gap 524 would typically comprise vacuum since fabrication and operation of the quantum systems is typically carried out under vacuum. In this context, it is understood that “vacuum” is an idealized term in that a perfect vacuum (i.e. zero pressure) can never be achieved in practical situations. Therefore, the term “vacuum” is used to cover non-zero pressures as long as they are sufficiently low to be considered nearly vacuum. In other embodiments, the gap 525 could contain air or any other gas or a mixture of gasses.

Finally, the photoresist 520 may be removed (process 610), e.g. using the aching process described above. FIG. 5D illustrates the Josephson Junction 514 suspended over the substrate 502 by means of the opening 524 provided under the Junction 514. As can be seen in FIG. 5D, due to the isotropic etching, both the x- and y-dimensions of the opening 524 would typically be greater than those of the window 522. For example, dimensions of the opening 524 in the x- and y-directions could be, between 50 and 2000 nm larger than the opening 522 in the photoresist. In order to fully suspend the junction 514, the undercut amount may be at least half the width of the junction in the y dimension.

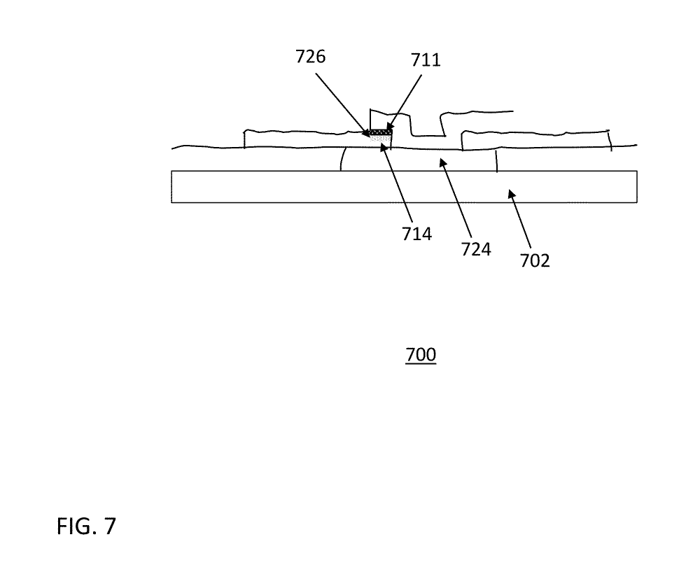

FIG. 7 provide a schematic illustration of a cross-section 700 of a structure comprising a suspended Josephson Junction 714, according to some embodiments of the present disclosure. As can be seen, FIG. 7 is drawn to reflect example real world process limitations, in that the features are not drawn with precise right angles and straight lines. As shown, FIG. 7 represents a cross-section view similar to that shown on the left side of FIG. 5D. The schematic is an example of the entire Josephson Junction 714 being suspended over the substrate 702 due to the opening 724. FIG. 7 illustrates a tunnel barrier layer 726 of the Josephson Junction 714, which would be visible in e.g. a scanning electron microscopy (SEM) image of a structure comprising the Josephson Junction 714. FIG. 7 also illustrates possible processing defects, such as e.g. the rounding of corners and the drooping of the suspended junction.

Some Examples in accordance with various embodiments of the present disclosure are now described.

Example 1 provides a qubit for use in a quantum circuit. The qubit includes a substrate; a Josephson Junction over the substrate; and a gap between at least a portion of the Josephson Junction and the substrate.

Example 2 provides the qubit according to Example 1, where the at least a portion of the Josephson Junction is suspended over the substrate to form a void between the at least a portion of the Josephson Junction and the substrate.

Example 3 provides the qubit according to Examples 1 or 2, where the Josephson Junction includes a base electrode layer, a top electrode layer, and a tunnel barrier layer located between the base electrode layer and the top electrode layer. The at least portion of the Josephson Junction may be a portion of the base electrode layer.

Example 4 provides the qubit according to Example 3, where the layers of the Josephson Junction (i.e. the base electrode layer, the top electrode layer, and the tunnel barrier layer) are substantially parallel to the substrate and the gap has a thickness between 10 and 300 nanometers (nm).

Example 5 provides the qubit according to Examples 3 or 4, where the base electrode layer and the top electrode layer are aluminum layers.

Example 6 provides the qubit according to any one of Examples 3-5, where the tunnel barrier layer is an aluminum oxide layer.

Example 7 provides the qubit according to any one of the preceding Examples, where the gap is between all of the Josephson Junction and the substrate.

Example 8 provides the qubit according to any one of the preceding Examples, where the qubit is a superconductive qubit.

Example 9 provides the qubit according to Example 8, where the superconductive qubit is a charge qubit.

Example 10 provides the qubit according to Examples 8 or 9, where the superconductive qubit is a transmon.

Example 11 provides the qubit according to any one of Examples 8-10, where the superconductive qubit further includes a capacitor.

Example 12 provides the qubit according to Example 8, where the superconductive qubit is a flux qubit.

Example 13 provides a quantum integrated circuit package, including a substrate; a first qubit provided over the substrate, the first qubit including a first Josephson Junction and a first gap between at least a portion of the first Josephson Junction and the substrate (i.e. at least a portion of the first Josephson Junction is suspended over the substrate forming a first gap between the at least portion of the first Josephson Junction and the substrate); and a second qubit provided over the substrate.

Example 14 provides the quantum integrated circuit package according to Example 13, where the second qubit includes a second Josephson Junction and a second gap between at least a portion of the second Josephson Junction and the substrate (i.e. at least a portion of the second Josephson Junction is suspended over the substrate forming a second gap between the at least portion of the second Josephson Junction and the substrate).

In a further example, any of the first and the second qubits could be a qubit according to any one of the Examples above.

Example 15 provides the quantum integrated circuit package according to Example 14, where the second gap is different from the first gap.

Example 16 provides the quantum integrated circuit package according any one of Examples 13-15, where the first qubit and the second qubit are coupled by a coupling resonator.

Example 17 provides a quantum computing device, including one or more integrated circuit packages according to any one of Examples 13-16.

Example 18 provides the quantum computing device according to Example 17, further including a cryogenic apparatus configured to maintain the first qubit and the second qubit at a cryogenic temperature during operation of the first qubit and the second qubit.

Example 19 provides a method for fabricating a qubit over a substrate, the method including: providing a layer of sacrificial material over the substrate; forming a Josephson Junction over the layer of sacrificial material; providing an etch mask over the substrate, the etch mask including a window over the Josephson Junction, the window configured to allow etch of the sacrificial material under at least portion of the Josephson Junction through the window; and performing the etch of at least portions of the sacrificial material through the window of the etch mask to provide a gap between at least a portion of the Josephson Junction and the substrate.

Example 20 provides the method according to Example 19, where the layer of sacrificial material includes silicon dioxide.

Example 21 provides the method according to Examples 19 or 20, where a thickness of the layer of sacrificial material is between 10 and 300 nm.

Example 22 provides the method according to any one of Examples 19-21, where the etch mask includes a photoresist mask patterned to form the window.

Example 23 provides the method according to any one of Examples 19-22, where forming the Josephson Junction includes using a double-angle shadow deposition method to form the Josephson Junction.

Example 24 provides the method according to Example 23, where the double-angle shadow deposition method includes: providing a deposition mask over the sacrificial material provided over the substrate, the deposition mask including a window on each side of a bridge suspended over an area of the sacrificial material on which the Josephson Junction is to be formed, depositing a layer of a first superconductive material through the deposition mask at a first angle with respect to the substrate, providing a layer of an insulating material over the layer of the first superconductive material, and depositing a layer of a second superconductive material through the deposition mask at a second angle with respect to the substrate.

Example 25 provides the method according to Example 24, where providing the layer of the insulating material includes oxidizing the layer of the first superconductive material.

Example 26 provides the method according to any one of Examples 19-25, further including removing the etch mask.

Example 27 provides the method according to any one of Examples 19-26, where the etch includes an isotropic etch.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A qubit for use in a quantum circuit, the qubit comprising:
a substrate;
a Josephson Junction over the substrate; and
a gap between at least a portion of the Josephson Junction and the substrate.

2. The qubit according to claim 1, wherein the at least a portion of the Josephson Junction is suspended over the substrate to form a void between the at least a portion of the Josephson Junction and the substrate.

3. The qubit according to claim 1, wherein the Josephson Junction comprises a base electrode layer, a top electrode layer, and a tunnel barrier layer located between the base electrode layer and the top electrode layer.

4. The qubit according to claim 3, wherein the layers of the Josephson Junction are substantially parallel to the substrate and the gap has a thickness between 10 and 300 nanometers (nm).

5. The qubit according to claim 3, wherein the base electrode layer and the top electrode layer are aluminum layers.

6. The qubit according to claim 3, wherein the tunnel barrier layer is an aluminum oxide layer.

7. The qubit according to claim 1, wherein the gap is between all of the Josephson Junction and the substrate.

8. The qubit according to claim 1, wherein the qubit is a superconductive qubit.

9. The qubit according to claim 8, wherein the superconductive qubit is a transmon.

10. The qubit according to claim 8, wherein the superconductive qubit further comprises a capacitor.

11. The qubit according to claim 8, wherein the superconductive qubit is a flux qubit.

12. A quantum integrated circuit package, comprising:
a substrate;
a first qubit provided over the substrate, the first qubit comprising a first Josephson Junction and a first gap between at least a portion of the first Josephson Junction and the substrate; and
a second qubit provided over the substrate.

13. The quantum integrated circuit package according to claim 12, wherein the second qubit comprises a second Josephson Junction and a second gap between at least a portion of the second Josephson Junction and the substrate.

14. The quantum integrated circuit package according to claim 13, wherein the second gap is different from the first gap.

15. The quantum integrated circuit package according to claim 12, wherein the first qubit and the second qubit are coupled by a coupling resonator.

16. (canceled)

17. (canceled)

18. A method for fabricating a qubit over a substrate, the method comprising:
providing a layer of sacrificial material over the substrate;
forming a Josephson Junction over the layer of sacrificial material;
providing an etch mask over the substrate, the etch mask comprising a window over the Josephson Junction, the window configured to allow etch of the sacrificial material under at least portion of the Josephson Junction through the window; and
performing the etch of at least portions of the sacrificial material through the window of the etch mask to provide a gap between at least a portion of the Josephson Junction and the substrate.

19. The method according to claim 18, wherein the layer of sacrificial material comprises silicon dioxide.

20. The method according to claim 18, wherein a thickness of the layer of sacrificial material is between 10 and 300 nm.

21. The method according to claim 18, wherein the etch mask comprises a photoresist mask patterned to form the window.

22. The method according to claim 18, wherein forming the Josephson Junction comprises using a double-angle shadow deposition method to form the Josephson Junction.

23. The method according to claim 22, wherein the double-angle shadow deposition method comprises:
providing a deposition mask over the sacrificial material provided over the substrate, the deposition mask comprising a window on each side of a bridge suspended over an area of the sacrificial material on which the Josephson Junction is to be formed,
depositing a layer of a first superconductive material through the deposition mask at a first angle with respect to the substrate,
providing a layer of an insulating material over the layer of the first superconductive material, and
depositing a layer of a second superconductive material through the deposition mask at a second angle with respect to the substrate.

24. The method according to claim 23, wherein providing the layer of the insulating material comprises oxidizing the layer of the first superconductive material.

25. The method according to claim 18, wherein the etch comprises an isotropic etch.
